(19) United States
(12) Patent Application Publication
(10) Pub. No.: US 2025/0015107 A1
(43) Pub. Date: Jan. 9, 2025

(54) PIXEL STRUCTURE, IMAGE SENSOR CHIP, CAMERA MODULE, AND ELECTRONIC DEVICE

(71) Applicant: VIVO MOBILE COMMUNICATION CO., LTD., Dongguan (CN)

(72) Inventor: Wangjun PAN, Dongguan (CN)

(73) Assignee: VIVO MOBILE COMMUNICATION CO., LTD., Dongguan (CN)

(21) Appl. No.: 18/890,847

(22) Filed: Sep. 20, 2024

Related U.S. Application Data
(63) Continuation of application No. PCT/CN2023/082081, filed on Mar. 17, 2023.

(30) Foreign Application Priority Data
Mar. 22, 2022 (CN) 202210286358.X

(51) Int. Cl. H01L 27/146

(52) U.S. Cl. CPC H01L 27/14625; H01L 27/14645

(57) ABSTRACT

This application provides a pixel structure, an image sensor chip, and an electronic device. The pixel structure includes a splitter and a photodiode. The photodiode includes a light-receiving surface, the light-receiving surface includes a plurality of light-receiving regions, and the splitter faces the light-receiving surface. The splitter includes a first optical layer and a second optical layer stacked, the first optical layer includes a first light-transmitting region and a second light-transmitting region, and the second optical layer includes a third light-transmitting region and a fourth light-transmitting region. Transmissivity of the first light-transmitting region and transmissivity of the second light-transmitting region are different, and transmissivity of the third light-transmitting region and transmissivity of the fourth light-transmitting region are different. A projection of the first light-transmitting region and a projection of the third light-transmitting region do not overlap in a direction perpendicular to the first optical layer.

### CROSS-REFERENCE TO RELATED APPLICATIONS

This application is a continuation of International Application No. PCT/CN2023/082081, filed on Mar. 17, 2023, which claims priority to Chinese Patent Application No. 202210286358.X, filed on Mar. 22, 2022. The entire contents of each of the above-referenced applications are expressly incorporated herein by reference.

### TECHNICAL FIELD

This application relates to the field of electronic device technologies, and in particular, to a pixel structure, an image sensor chip, a camera module, and an electronic device.

### BACKGROUND

With the development of science, electronic devices are used increasingly more widely. Generally, the electronic device includes a camera module, an image sensor chip is disposed in the camera module, and a pixel structure is disposed on the image sensor chip. When photographing is performed by using the electronic device, incident light is finally irradiated on the pixel structure, and the pixel structure may convert the incident light into an electrical signal and transmit the electrical signal to the image sensor chip.

In a related technology, the pixel structure includes a microlens structure, a filter, and a photodiode, and the microlens structure, the filter, and the photodiode are stacked. The incident light may pass through the microlens structure, then passes through the filter, and is finally irradiated on the photodiode, so that the photodiode can convert an optical signal into an electrical signal.

However, in a related technology, when the incident light passes through the filter, the filter absorbs a part of the incident light, which affects conversion efficiency of the photodiode.

### SUMMARY

Embodiments of this application provide a pixel structure, an image sensor chip, a camera module, and an electronic device, to resolve a problem in a related technology that conversion efficiency of a photodiode is affected because a filter absorbs a part of incident light when the incident light passes through the filter.

To resolve the foregoing technical problem, this application is implemented as follows.

According to a first aspect, an embodiment of this application provides a pixel structure. The pixel structure includes a splitter and a photodiode.

The photodiode includes a light-receiving surface, the light-receiving surface includes a plurality of light-receiving regions, and the splitter faces the light-receiving surface.

The splitter includes a first optical layer and a second optical layer stacked, the first optical layer includes a first light-transmitting region and a second light-transmitting region, and the second optical layer includes a third light-transmitting region and a fourth light-transmitting region.

Transmissivity of the first light-transmitting region and transmissivity of the second light-transmitting region are different, transmissivity of the third light-transmitting region and transmissivity of the fourth light-transmitting region are different, a projection of the first light-transmitting region and a projection of the third light-transmitting region do not overlap in a direction perpendicular to the first optical layer, beams on different bands are formed after incident light passes through the splitter, and the beams on the different bands are respectively received by corresponding light-receiving regions.

According to a second aspect, an embodiment of this application provides an image sensor chip. The image sensor chip includes a plurality of pixel structures according to the first aspect, and the plurality of pixel structures are arranged densely.

According to a third aspect, an embodiment of this application provides a camera module, including the image sensor chip according to the second aspect.

According to a fourth aspect, an embodiment of this application provides an electronic device, including a housing and the camera module according to the third aspect, and a partial structure of the camera module is embedded in the housing.

In the embodiments of this application, the splitter includes stacked single-layer structures. In the single-layer structure, two layers are spliced by at least two types of optical units. Refractive indexes of any two types of optical units in the at least two types of optical units are different, and the optical unit is a transparent structure. Therefore, after incident light is irradiated on the splitter, the incident light passes through the splitter, and the incident light is split into beams on three or four different bands. The splitter faces the light-receiving surface, and the light-receiving surface includes four light-receiving regions. Therefore, after the incident light is split into the beams on three or four different bands, the beams on the different bands are respectively irradiated on light-receiving regions corresponding to the beams. In the embodiments of this application, the splitter is disposed, and the splitter can split the incident light into beams on three or four different bands, so that the beams on the different bands are respectively irradiated on light-receiving regions corresponding to the beams, thereby preventing loss of energy of the incident light that is caused when a part of light in a beam irradiated on the light-receiving region is filtered by a filter. Therefore, energy of the incident light received in the light-receiving region can be improved, and conversion efficiency of the photodiode is higher.

### BRIEF DESCRIPTION OF DRAWINGS

FIG. 1 is a schematic diagram of a pixel structure according to an embodiment of this application;

FIG. 2 is a schematic diagram of a splitter according to an embodiment of this application;

FIG. 3 is a diagram of a principle of a pixel structure according to an embodiment of this application;

FIG. 4 is a schematic diagram of a first optical unit according to an embodiment of this application;

FIG. 5 is a schematic diagram of a first optical layer according to an embodiment of this application; and

FIG. 6 is a schematic diagram of a pixel structure in a related technology.

### REFERENCE NUMERALS

10: Splitter; 20: Photodiode; 11: First optical layer; 12: Second optical layer; 21: Light-receiving region; 100: Microlens structure; 200: Filter.

### DETAILED DESCRIPTION

The following clearly describes the technical solutions in the embodiments of this application with reference to the accompanying drawings in the embodiments of this application. Apparently, the described embodiments are some but not all of the embodiments of this application. All other embodiments obtained by a person of ordinary skill in the art based on embodiments of this application without creative efforts shall fall within the protection scope of this application.

It should be understood that “one embodiment” or “an embodiment” mentioned throughout the specification means that a specific feature, structure, or characteristic related to the embodiments is included in at least one embodiment of this application. Therefore, “in one embodiment” or “in an embodiment” appearing throughout the specification does not necessarily refer to a same embodiment. In addition, these specific features, structures, or characteristics may be incorporated in one or more embodiments in any proper manner.

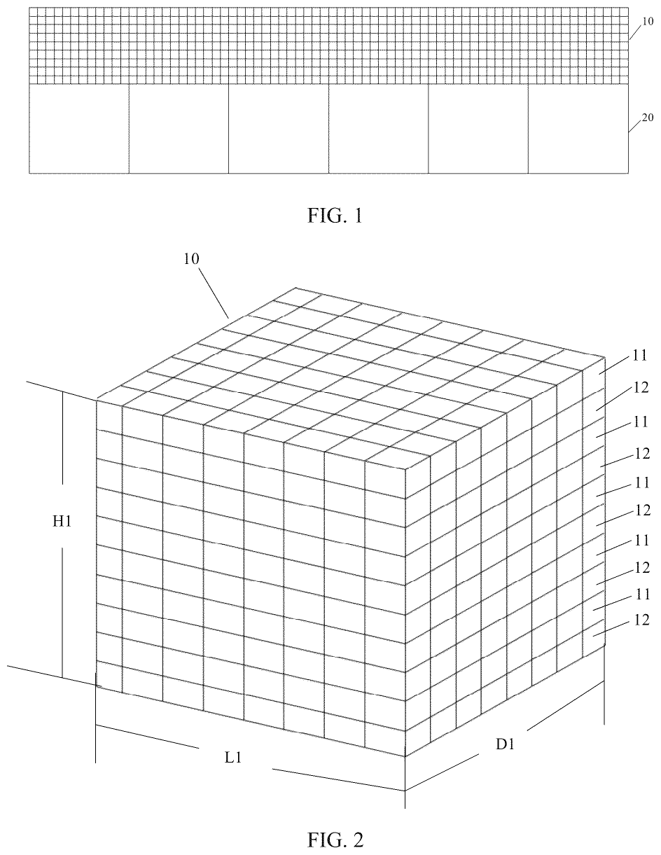

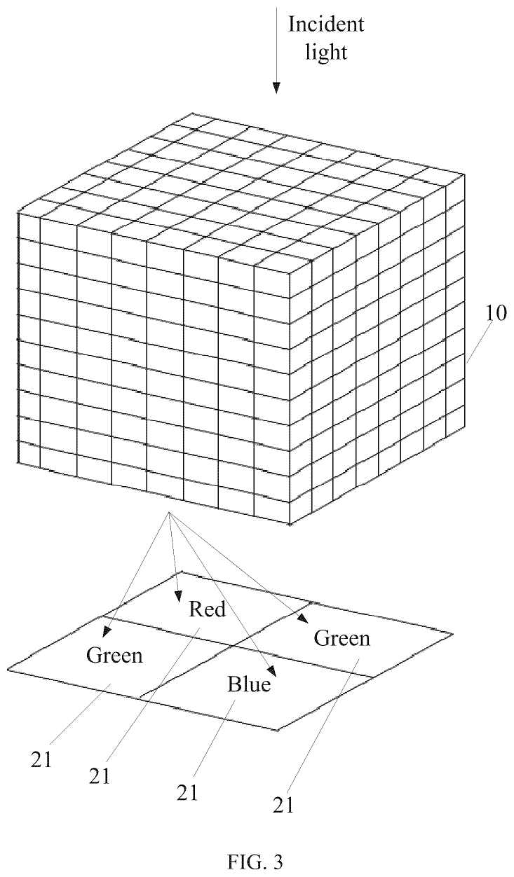

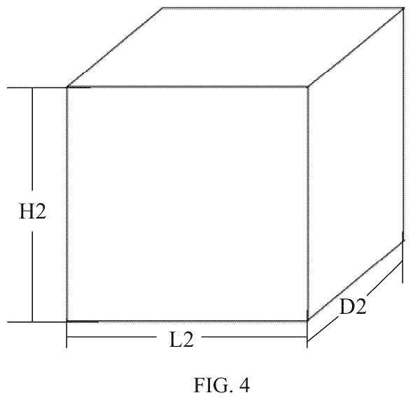

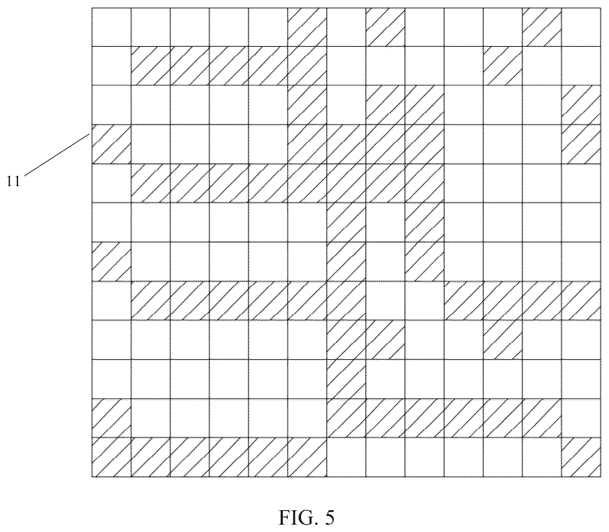

FIG. 1 is a schematic diagram of a pixel structure according to an embodiment of this application. FIG. 2 is a schematic diagram of a splitter according to an embodiment of this application. FIG. 3 is a diagram of a principle of a pixel structure according to an embodiment of this application. FIG. 4 is a schematic diagram of an optical unit according to an embodiment of this application. FIG. 5 is a schematic diagram of a single-layer structure according to an embodiment of this application. As shown in FIG. 1 to FIG. 5, the pixel structure includes a splitter 10 and a photodiode 20.

The photodiode 20 includes a light-receiving surface. The light-receiving surface includes a plurality of light-receiving regions 21. The splitter 10 faces the light-receiving surface. The splitter 10 includes a first optical layer 11 and a second optical layer 12 stacked, the first optical layer 11 includes a first light-transmitting region and a second light-transmitting region, and the second optical layer 12 includes a third light-transmitting region and a fourth light-transmitting region. Transmissivity of the first light-transmitting region and transmissivity of the second light-transmitting region are different, transmissivity of the third light-transmitting region and transmissivity of the fourth light-transmitting region are different, a projection of the first light-transmitting region and a projection of the third light-transmitting region do not overlap in a direction perpendicular to the first optical layer, beams on different bands are formed after incident light passes through the splitter, and the beams on the different bands are respectively received by corresponding light-receiving regions 21.

In this embodiment of this application, the splitter 10 includes the first optical layer 11 and the second optical layer 12 stacked, the first optical layer 11 includes the first light-transmitting region and the second light-transmitting region, and the second optical layer 12 includes the third light-transmitting region and the fourth light-transmitting region. The transmissivity of the first light-transmitting region and the transmissivity of the second light-transmitting region are different, the transmissivity of the third light-transmitting region and the transmissivity of the fourth light-transmitting region are different, and the projection of the first light-transmitting region and the projection of the third light-transmitting region do not overlap in the direction perpendicular to the first optical layer. Therefore, after the incident light is irradiated on the splitter 10, the incident light passes through the splitter 10, and the incident light is split into beams on a plurality of different bands. The splitter 10 faces the light-receiving surface, and the light-receiving surface includes the plurality of light-receiving regions 21. Therefore, after the incident light is split into the beams on the plurality of different bands, the beams on the different bands are respectively irradiated on light-receiving regions 21 corresponding to the beams. In this embodiment of this application, the splitter 10 is disposed, and the splitter 10 can split the incident light into beams on a plurality of different bands, so that the beams on the different bands are respectively irradiated on light-receiving regions 21 corresponding to the beams, thereby preventing loss of energy of the incident light that is caused when a part of light in a beam irradiated on the light-receiving region 21 is filtered by a filter 200. Therefore, energy of the incident light received in the light-receiving region 21 can be improved, and conversion efficiency of the photodiode 20 is higher.

It should be noted that in this embodiment of this application, the plurality of light-receiving regions 21 may include a red light region, a blue light region, and two green light regions. The plurality of light-receiving regions 21 may, for example, include a red light region, a blue light region, and a green light region. Beams on different bands have different color. For example, light on a band of 400 nanometers to 500 nanometers is blue light, light on a band of 500 nanometers to 600 nanometers is green light, and light on a band of 600 nanometers to 700 nanometers is red light. In addition, in this embodiment of this application, the photodiode 20 is configured to convert an optical signal into an electrical signal, that is, light irradiated on the light-receiving surface of the photodiode 20, that is, the optical signal, can be converted into an electrical signal by the photodiode 20.

It should be noted that, in this embodiment of this application, the incident light is irradiated on the splitter 10, and the splitter 10 may split the incident light into beams on three or four different bands, so that the beams on the different bands are respectively irradiated on light-receiving regions 21 corresponding to the beams.

In addition, in this embodiment of this application, a projection of the second light-transmitting region and a projection of the fourth light-transmitting region do not overlap in the direction perpendicular to the first optical layer. The projection of the second light-transmitting region and the projection of the fourth light-transmitting region may, for example, overlap. This is not limited in this embodiment of this application.

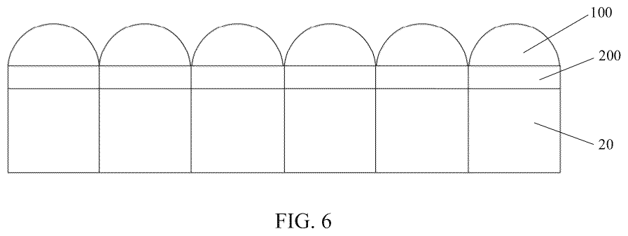

In addition, in a related technology, as shown in FIG. 6, a pixel structure includes a microlens structure 100, a filter 200, and a photodiode 20. The photodiode 20 includes a light-receiving surface. The light-receiving surface includes four light-receiving regions 21. The microlens structure 100, the filter 200, and the photodiode 20 are stacked, and one filter 200 corresponds to one light-receiving region 21. After incident light is irradiated on the microlens structure 100, the incident light passes through the microlens structure 100, and then passes through the filter 200. The filter 200 filters out stray light in the incident light, so that color of a beam passing through the filter 200 is the same as color of a light-receiving region 21 corresponding to the filter 200. For example, the four light-receiving regions 21 are respectively a red light region, a blue light region, and two green light regions, the red light region corresponds to a red light filter 200, the blue light region corresponds to a blue light filter 200, and the green light region corresponds to a green light filter 200. After the incident light passes through a microlens, the incident light is irradiated on the filter 200. In this case, the red light filter 200 may filter out stray light in the incident light, and only red light is allowed to pass through the red light filter 200 and be irradiated on the red light region; the green light filter 200 may filter out stray light in the incident light, and only green light is allowed to pass through the green light filter 200 and be irradiated on the green light region; and the blue light filter 200 may filter out stray light in the incident light, and only blue light is allowed to be irradiated on the blue light region.

However, stray light filtered out by a filter 200 of each color further includes light in another color. For example, when the red light filter 200 filters out the stray light in the incident light, the stray light also includes green light and blue light, which is equivalent to that the red light filter 200 absorbs the blue light and the green light. Consequently, less blue light and less green light are irradiated on the blue light region and the green light region, and energy in the incident light is lost significantly. In other words, in the related technology, total energy of beams irradiated on the four light-receiving regions 21 is less than total energy of the incident light, and some energy is absorbed by the filter 200.

In this embodiment of this application, the splitter 10 is disposed. When the incident light passes through the splitter 10, the incident light is split into beams on a plurality of bands, and the beams on the different bands are irradiated on light-receiving regions 21 corresponding to different color, which is equivalent to splitting the incident light, and beams on different bands are irradiated on different light-receiving regions 21 after being split. Therefore, total energy of the beams irradiated on the four light-receiving regions 21 is close to or equal to the total energy of the incident light. In other words, energy loss of the incident light is relatively small or there is no loss, so that energy of a beam irradiated on each light-receiving region 21 is enhanced.

In addition, in this embodiment of this application, the splitter 10 may be formed by using a photolithography method. To be specific, one first optical layer 11 is first etched on a substrate by using the photolithography method, where the substrate may be a transparent material; then an etching position is filled with another transparent material to form a complete optical layer; then, the second optical layer 12 is formed in a same manner, and a plurality of first optical layers 11 and a plurality of second optical layers 12 may be formed; and then, the plurality of first optical layers 11 and the plurality of second optical layers 12 are stacked to form the splitter 10. The splitter 10 may be, for example, formed by using a nanoimprint process, or the splitter 10 may be formed in a three-dimensional printing manner. This is not limited in this embodiment of this application.

In addition, in this embodiment of this application, in a case that the incident light is visible light, the incident light passes through the splitter 10, and the incident light is split into beams on three different bands; and in a case that the incident light includes visible light and invisible light, the incident light passes through the splitter 10, and the incident light is split into beams on four different bands.

The visible light is white light, and the invisible light includes infrared light, ultraviolet light, and the like. A wavelength range of the visible light is 380 nanometers to 750 nanometers, and a wavelength of the invisible light is greater than 750 nanometers.

In addition, when the incident light is the visible light, after the visible light passes through the splitter 10, the visible light may be split into red light, green light, and blue light. When the incident light includes the visible light and the invisible light, for example, the incident light includes white light and infrared light, after the white light and the infrared light pass through the splitter 10, the white light is split into red light, green light, and blue light. A band of the infrared light is not affected, that is, when the incident light includes the white light and the infrared light, light passing through the splitter 10 includes the red light, the blue light, the green light, and the infrared light.

For example, as shown in FIG. 3, the incident light is white light, and after the white light passes through the splitter 10, the white light is split into red light, blue light, and green light, where the red light is irradiated on the red light region, the green light is irradiated on the green light region, and the blue light is irradiated on the blue light region. The red light region, the blue light region, and the green light region are all light-receiving regions 21.

It should be noted that, in this embodiment of this application, that the incident light can be split into beams on three bands or four bands is exactly based on the first optical layer 11 and the second optical layer 12 of the splitter 10 stacked. The first optical layer 11 includes the first light-transmitting region and the second light-transmitting region, and the second optical layer 12 includes the third light-transmitting region and the fourth light-transmitting region. Therefore, when the incident light passes through the splitter 10, the incident light passes through different light-transmitting regions in sequence, and when the incident light passes through different light-transmitting regions, because the transmissivity of the first light-transmitting region and the transmissivity of the second light-transmitting region are different, the transmissivity of the third light-transmitting region and the transmissivity of the fourth light-transmitting region are different, and the projection of the first light-transmitting region and the projection of the third light-transmitting region do not overlap, the incident light is refracted to different degrees, so that after the incident light passes through the splitter 10, the incident light can be split into beams on three bands or four bands.

In addition, the first light-transmitting region and the second light-transmitting region may be arranged in a preset manner, or certainly, may be arranged according to an actual requirement. For example, as shown in FIG. 5, the first optical layer includes the first light-transmitting region and the second light-transmitting region, where filled squares represent the first light-transmitting region, and blank squares represent the second light-transmitting region.

In addition, in this embodiment of this application, the first light-transmitting region may include a plurality of first optical units, the second light-transmitting region may include a plurality of second optical units, a shape of the first optical unit and a shape of the second optical unit are the same, a size of the first optical unit and a size of the second optical unit are equal, and transmissivity of the first optical unit and transmissivity of the second optical unit are different. For example, as shown in FIG. 5, one filled square in the filled squares represents one first optical unit, and one blank square in the blank squares represents one second optical unit.

In a case that the shape of the first optical unit is the same as the shape of the second optical unit and the size of the first optical unit is equal to the size of the second optical unit, when the first optical unit and the second optical unit are separately spliced to form the first light-transmitting region and the second light-transmitting region, and then the first optical layer 11 is formed, splicing is facilitated, and thickness of the formed first optical layer 11 is uniform.

In addition, in this embodiment of this application, the third light-transmitting region may include a plurality of third optical units, the fourth light-transmitting region may include a plurality of fourth optical units, a shape of the third optical unit and a shape of the fourth optical unit are the same, a size of the third optical unit and a size of the fourth optical unit are equal, and transmissivity of the third optical unit and transmissivity of the fourth optical unit are different.

In this embodiment of this application, a sorting manner of optical units with different refractive indexes in the first light-transmitting region and the second light-transmitting region may be changed, that is, a sorting manner of the first optical unit and the second optical unit may be changed, so that the splitter 10 can split the visible light into beams on three bands, and split the visible light and the invisible light into beams on four bands. When the splitter 10 splits the visible light into beams on only three bands, the splitter 10 is equivalent to having three channels. When the splitter 10 can split the visible light and the invisible light into beams on four bands, the splitter 10 is equivalent to having four channels. When the splitter 10 has four channels, an optical structure is applied to an image sensor chip, and then the image sensor chip is applied to a camera module. In this case, the infrared filter 200 in the camera module can be saved, that is, the infrared filter 200 is not required in the camera module, thereby reducing costs of the camera module. The camera module usually includes a housing, the infrared filter 200, and the image sensor chip.

In addition, when the first optical layer includes two optical units with different refractive indexes, a difference between the refractive indexes of the two optical units with different refractive indexes is relatively large, that is, the difference between the refractive indexes of the two optical units with different refractive indexes needs to be greater than or equal to a preset threshold. When the first optical layer includes three optical units with different refractive indexes, a difference between refractive indexes of any two optical units with different refractive indexes is relatively large, that is, the difference between refractive indexes of any two optical units with different refractive indexes is greater than or equal to the preset threshold.

For example, the preset threshold is 2. When the first optical layer includes an optical unit A and an optical unit B, a difference between a refractive index of the optical unit A and a refractive index of the optical unit B is greater than or equal to 2. When the first optical layer 11 includes three types of optical units, that is, the first optical layer 11 includes an optical unit A, an optical unit B, and an optical unit C, a difference between a refractive index of the optical unit A and a refractive index of the optical unit B is greater than or equal to 2, a difference between the refractive index of the optical unit A and a refractive index of the optical unit C is greater than or equal to 2, and a difference between the refractive index of the optical unit B and the refractive index of the optical unit C is greater than or equal to 2.

The first optical layer 11 may further include four or even more types of optical units. In this case, a difference between refractive indexes of any two optical units is greater than or equal to the preset threshold. In other words, when the first optical layer includes at least two types of optical units, a difference between refractive indexes of any two types of optical units is greater than or equal to the preset threshold.

It should be noted that the second optical layer 12 may, for example, include more than two types of optical units, and a difference between refractive indexes of any two types of optical units is greater than or equal to the preset threshold.

In addition, in this embodiment of this application, both the first optical unit and the second optical unit may be made of one or more of silicon dioxide, silicon nitride, titanium dioxide, or gallium nitride. In other words, any type of optical unit may be made of one or more of silicon dioxide, silicon nitride, titanium dioxide, or gallium nitride. In this case, when the first optical unit may be made of silicon dioxide, the second optical unit may be made of silicon nitride. When the first optical layer includes three types of optical units, the first optical unit may be made of silicon dioxide, the second optical unit may be made of silicon nitride, and a last optical unit may be made of titanium dioxide.

In addition, in this embodiment of this application, both the first optical unit and the second optical unit may be quadrangular prism structures.

In a case that the first optical unit and the second optical unit are quadrangular prism structures, when the first optical unit and the second optical unit are spliced to form the first optical layer 11, splicing can be facilitated.

In addition, in some embodiments, a length range, a width range, and a height range of the quadrangular prism structure each may be 10 nanometers to 200 nanometers, and a height direction of the quadrangular prism structure is the same as a thickness direction of the splitter 10. In other words, a length range, a width range, and a height range of the first optical unit and a length range, a width range, and a height range of the second optical unit may be 10 nanometers to 200 nanometers, that is, a size range of the quadrangular prism structure in any direction is 10 nanometers to 200 nanometers.

When the length range, the width range, and the height range of the first optical unit and the length range, the width range, and the height range of the second optical unit may be 10 nanometers to 200 nanometers, a volume of the first optical unit and a volume of the second optical unit are relatively small, so that the first optical layer 11 may be formed by using the first optical unit and the second optical unit that are relatively small, and a refractive index of the first optical unit and a refractive index of the second optical unit are different. In addition, the second optical layer includes a third optical unit and a fourth optical unit. Both the first optical unit and the second optical unit may be quadrangular prism structures. A length range, a width range, and a height range of the quadrangular prism structure may be 10 nanometers to 200 nanometers, and a height direction of the quadrangular prism structure is the same as the thickness direction of the splitter 10. In other words, the length range, the width range, and the height range of the first optical unit and the length range, the width range, and the height range of the second optical unit may be 10 nanometers to 200 nanometers. Therefore, when the incident light passes through the first optical layer 11 and the second optical layer 12, the incident light can be better refracted. This helps the splitter 10 split the incident light into beams on three bands or four bands when the incident light passes through the splitter 10.

For example, as shown in FIG. 4, height of the first optical unit may be H2, a range of H2 may be 10 nanometers to 200 nanometers, length of the first optical unit may be L2, a range of L2 may be 10 nanometers to 200 nanometers, width of the first optical unit may be D2, and a range of D2 may be 10 nanometers to 200 nanometers.

In addition, in actual application, the height of the first optical unit or the second optical unit may be any value in 10 nanometers to 200 nanometers. For example, the height of the first optical unit may be 10 nanometers, 20 nanometers, 40 nanometers, 80 nanometers, 140 nanometers, 180 nanometers, or 200 nanometers. The length of the first optical unit may be any value in 10 nanometers to 200 nanometers. For example, the length of the first optical unit may be 10 nanometers, 20 nanometers, 40 nanometers, 80 nanometers, 140 nanometers, 180 nanometers, or 200 nanometers. The width of the first optical unit may be any value in 10 nanometers to 200 nanometers. For example, the width of the first optical unit may be 10 nanometers, 20 nanometers, 40 nanometers, 80 nanometers, 140 nanometers, 180 nanometers, or 200 nanometers.

It should be noted that, in this embodiment of this application, a size of the third optical unit and a size of the first optical unit may be the same, that is, length, width, and height of the third optical unit are equal to length, width, and height of the first optical unit.

In addition, in some embodiments, a thickness range of the splitter 10 may be 1 micron to 10 microns, and thickness of the splitter 10 is a distance between a surface of the splitter 10 that is away from the photodiode and a surface that faces the photodiode.

When the thickness range of the splitter is 1 micron to 10 microns, the thickness of the splitter is relatively small, so that a volume of the pixel structure is relatively small, and therefore, when the pixel structure is applied to the image sensor chip, reduction of thickness of the image sensor chip is facilitated.

In addition, in some embodiments, the splitter 10 may also be a quadriboid structure. A height range of the optical layer is 1 micron to 10 microns, and a length range and a width range of the optical layer are 0.8 microns to 10 microns. Height of the splitter 10 is a distance from a surface away from the photodiode 20 and a surface facing the photodiode 20.

When a height range of the splitter 10 is 1 micron to 10 microns and both a length range and a width range are 0.8 microns to 10 microns, a volume of the splitter 10 is relatively small, so that a volume of the pixel structure is relatively small, and when the pixel structure is applied to the image sensor chip, reduction of thickness of the image sensor chip is facilitated.

For example, as shown in FIG. 2, the splitter 10 is a quadriboid structure, height of an optical structure layer is H1, a range of H1 is 1 micron to 10 microns, length of the optical structure layer is L1, a range of L1 is 0.8 microns to 10 microns, width of the optical structure layer is D1, and a range of D1 is 0.8 microns to 10 microns.

In addition, in actual application, the height of the splitter 10 may be any value in 1 micron to 10 microns. For example, the height of the splitter 10 may be 1 micron, 2 microns, 4 microns, 8 microns, or 10 microns. The length of the splitter 10 may be any value in 0.8 microns to 10 microns. For example, the length of the splitter 10 may be 0.8 microns, 2 microns, 4 microns, 8 microns, or 10 microns. The width of the splitter 10 may be any value in 0.8 microns to 10 microns. For example, the width of the splitter 10 may be 0.8 microns, 2 microns, 4 microns, 8 microns, or 10 microns.

In addition, in this embodiment of this application, the splitter 10 may be alternatively another structure. For example, the splitter 10 may further form a trapezoidal structure, a cylindrical structure, a quadrangular prism, and the like by using a single-layer structure. A specific shape of the splitter 10 is not limited in this embodiment of this application.

In this embodiment of this application, the splitter 10 includes the first optical layer 11 and the second optical layer 12 stacked, the first optical layer 11 includes the first light-transmitting region and the second light-transmitting region, and the second optical layer 12 includes the third light-transmitting region and the fourth light-transmitting region. The transmissivity of the first light-transmitting region and the transmissivity of the second light-transmitting region are different, the transmissivity of the third light-transmitting region and the transmissivity of the fourth light-transmitting region are different, and the projection of the first light-transmitting region and the projection of the third light-transmitting region do not overlap in the direction perpendicular to the first optical layer. Therefore, after the incident light is irradiated on the splitter 10, the incident light passes through the splitter 10, and the incident light is split into beams on a plurality of different bands. The splitter 10 faces the light-receiving surface, and the light-receiving surface includes the plurality of light-receiving regions 21. Therefore, after the incident light is split into the beams on the plurality of different bands, the beams on the different bands are respectively irradiated on light-receiving regions 21 corresponding to the beams. In this embodiment of this application, the splitter 10 is disposed, and the splitter 10 can split the incident light into beams on a plurality of different bands, so that the beams on the different bands are respectively irradiated on light-receiving regions 21 corresponding to the beams, thereby preventing loss of energy of the incident light that is caused when a part of light in a beam irradiated on the light-receiving region 21 is filtered by the filter 200. Therefore, energy of the incident light received in the light-receiving region 21 can be improved, and conversion efficiency of the photodiode 20 is higher.

An embodiment of this application provides an image sensor chip. The image sensor chip includes a plurality of pixel structures in any one of the plurality of embodiments, and the plurality of pixel structures are arranged densely.

The image sensor chip includes a setting surface, the plurality of pixel structures are arranged densely on the setting surface, and a photodiode of each pixel structure is disposed on the setting surface. In addition, when the plurality of pixel structures are arranged densely on the setting surface of the image sensor chip, after light is irradiated on an image sensor, the light is first irradiated on a splitter of each pixel structure, and the splitter splits the incident light into a plurality of beams on different bands, so that the beams on the different bands are separately irradiated on light-receiving regions corresponding to the beams, thereby preventing loss of energy of the incident light that is caused when a part of light in a beam irradiated in the light-receiving region is filtered by a filter. Therefore, energy of the incident light received in the light-receiving region can be improved, and conversion efficiency of the photodiode is higher. Therefore, conversion efficiency of the image sensor chip can be improved.

It should be noted that, that the plurality of pixel structures are arranged densely means that the plurality of pixel structures are arranged on the setting surface of the image sensor in a manner of being adjacent to each other. In other words, any pixel structure is adjacent to at least one other pixel structure.

An embodiment of this application provides a camera module, and the camera module includes the image sensor in the foregoing embodiment.

The camera module may include a housing, a lens assembly, a filter, a circuit board, and an image sensor. Both the lens assembly and the filter are located in the housing, the lens assembly and the filter are disposed at an interval, the circuit board is disposed on a side of the filter that is away from the lens assembly, the image sensor is disposed on the circuit board, the image sensor is disposed in the housing, and the image sensor faces the filter. Therefore, light may pass through the lens assembly, then the light is irradiated on the filter, and then the light passing through the filter is irradiated on the image sensor. In other words, the light passing through the filter is irradiated on the splitter first, and then is irradiated on the photodiode, so that the photodiode converts an optical signal of the light into an electrical signal.

In addition, when the light is irradiated on the splitter, the splitter splits the incident light into a plurality of beams on different bands, so that the beams on the different bands are separately irradiated on light-receiving regions corresponding to the beams. Therefore, energy of the incident light received in the light-receiving region can be improved, conversion efficiency of the photodiode is higher, conversion efficiency of the image sensor chip can be improved, and finally a photographing effect of the camera module can be improved.

An embodiment of this application provides an electronic device. The electronic device includes a housing and the camera module in the foregoing embodiment. A partial structure of the camera module is embedded in the housing.

When photographing is performed by using the electronic device, light passes through a light-transmitting component in the camera module, and then the light is irradiated on a filter. Then, the light passing through the filter is irradiated on an image sensor. In other words, the light passing through the filter is irradiated on a splitter first, and then is irradiated on a photodiode, so that the photodiode converts an optical signal of the light into an electrical signal. The splitter may split the incident light into a plurality of beams on different bands, so that the beams on the different bands are separately irradiated on light-receiving regions corresponding to the beams. Therefore, energy of the incident light received in the light-receiving region can be improved, conversion efficiency of the photodiode is higher, conversion efficiency of the image sensor chip can be improved, and finally a photographing effect of the camera module can be improved. Therefore, performance of the electronic device can be improved.

It should be noted that, in this embodiment of this application, the electronic device includes but is not limited to a mobile phone, a notebook computer, a smart watch, and the like. In addition, the camera module may be a front-facing camera of the electronic device, or may be a rear-facing camera of the electronic device. This is not limited in this embodiment of this application.

It should be noted that each embodiment in this specification is described in a progressive manner, each embodiment focuses on the difference from other embodiments, and the same and similar parts between the embodiments may refer to each other.

Although optional embodiments of this application have been described, those skilled in the art may make additional changes and modifications to these embodiments once they learn the basic inventive concept. Therefore, the appended claims are intended to be interpreted as including the optional embodiments and all changes and modifications that fall within the scope of the embodiments of this application.

Finally, it should be further noted that, in this specification, relationship terms such as first and second are only used to distinguish an entity from another entity, but do not necessarily require or imply that there is any actual relationship or order between these entities. Moreover, the terms “include”, “comprise”, or any of their variants are intended to cover a non-exclusive inclusion, so that an article or a terminal device that includes a list of elements not only includes those elements but also includes other elements that are not listed, or further includes elements inherent to such an article or terminal device. In absence of more constraints, an element preceded by “includes a . . . ” does not preclude the existence of other identical elements in the article or the terminal device that includes the element.

The technical solutions provided in this application are described above in detail. A specific example is used in this specification to describe the principles and implementations of this application. Meanwhile, a person of ordinary skill in the art may change a specific implementation and an application scope according to the principles and implementations of this application. In conclusion, content of this specification should not be construed as a limitation of this application.

1. A pixel structure, comprising:
a splitter comprising a first optical layer and a second optical layer stacked, wherein the first optical layer comprises a first light-transmitting region and a second light-transmitting region, and the second optical layer comprises a third light-transmitting region and a fourth light-transmitting region; and
a photodiode comprising a light-receiving surface, wherein the light-receiving surface comprises a plurality of light-receiving regions, and the splitter faces the light-receiving surface,
wherein transmissivity of the first light-transmitting region and transmissivity of the second light-transmitting region are different, transmissivity of the third light-transmitting region and transmissivity of the fourth light-transmitting region are different, a projection of the first light-transmitting region and a projection of the third light-transmitting region do not overlap in a direction perpendicular to the first optical layer, beams on different bands are formed after incident light passes through the splitter, and the beams on the different bands are respectively received by corresponding light-receiving regions.

2. The pixel structure according to claim 1, wherein the first light-transmitting region comprises a plurality of first optical units, the second light-transmitting region comprises a plurality of second optical units, a shape of the first optical unit and a shape of the second optical unit are the same, a size of the first optical unit and a size of the second optical unit are equal, and transmissivity of the first optical unit and transmissivity of the second optical unit are different.

3. The pixel structure according to claim 2, wherein both the first optical unit and the second optical unit are quadrangular prism structures.

4. The pixel structure according to claim 3, wherein a size range of the quadrangular prism structure in any direction is from 10 nanometers to 200 nanometers.

5. The pixel structure according to claim 1, wherein when the incident light is visible light, the beams on three different bands are formed after the incident light passes through the splitter; and
when the incident light comprises visible light and invisible light, the beams on four different bands are formed after the incident light passes through the splitter.

6. The pixel structure according to claim 1, wherein a thickness range of the splitter is from 1 micron to 10 microns, and thickness of the splitter is a distance between a surface of the splitter facing away from the photodiode and a surface facing toward the photodiode.

7. The pixel structure according to claim 2, wherein the first optical unit and the second optical unit are each made of one or more of silicon dioxide, silicon nitride, titanium dioxide, or gallium nitride.

8. An image sensor chip, comprising a plurality of pixel structures, wherein the plurality of pixel structures are arranged at a density exceeding a threshold,
wherein the pixel structure comprises:
a splitter comprising a first optical layer and a second optical layer stacked, wherein the first optical layer comprises a first light-transmitting region and a second light-transmitting region, and the second optical layer comprises a third light-transmitting region and a fourth light-transmitting region; and
a photodiode comprising a light-receiving surface, wherein the light-receiving surface comprises a plurality of light-receiving regions, and the splitter faces the light-receiving surface,
wherein transmissivity of the first light-transmitting region and transmissivity of the second light-transmitting region are different, transmissivity of the third light-transmitting region and transmissivity of the fourth light-transmitting region are different, a projection of the first light-transmitting region and a projection of the third light-transmitting region do not overlap in a direction perpendicular to the first optical layer, beams on different bands are formed after incident light passes through the splitter, and the beams on the different bands are respectively received by corresponding light-receiving regions.

9. The image sensor chip according to claim 8, wherein the first light-transmitting region comprises a plurality of first optical units, the second light-transmitting region comprises a plurality of second optical units, a shape of the first optical unit and a shape of the second optical unit are the same, a size of the first optical unit and a size of the second optical unit are equal, and transmissivity of the first optical unit and transmissivity of the second optical unit are different.

10. The image sensor chip according to claim 9, wherein both the first optical unit and the second optical unit are quadrangular prism structures.

11. The image sensor chip according to claim 10, wherein a size range of the quadrangular prism structure in any direction is from 10 nanometers to 200 nanometers.

12. The image sensor chip according to claim 8, wherein when the incident light is visible light, the beams on three different bands are formed after the incident light passes through the splitter; and
when the incident light comprises visible light and invisible light, the beams on four different bands are formed after the incident light passes through the splitter.

13. The image sensor chip according to claim 8, wherein a thickness range of the splitter is from 1 micron to 10 microns, and thickness of the splitter is a distance between a surface of the splitter facing away from the photodiode and a surface facing toward the photodiode.

14. The image sensor chip according to claim 9, wherein the first optical unit and the second optical unit are each made of one or more of silicon dioxide, silicon nitride, titanium dioxide, or gallium nitride.

15. An electronic device, comprising a housing and a camera module, wherein the camera module comprises an image sensor chip, the image sensor chip comprises a plurality of pixel structures, and the plurality of pixel structures are arranged at a density exceeding a threshold,
wherein the pixel structure comprises:
a splitter comprising a first optical layer and a second optical layer stacked, wherein the first optical layer comprises a first light-transmitting region and a second light-transmitting region, and the second optical layer comprises a third light-transmitting region and a fourth light-transmitting region; and
a photodiode comprising a light-receiving surface, wherein the light-receiving surface comprises a plurality of light-receiving regions, and the splitter faces the light-receiving surface,
wherein transmissivity of the first light-transmitting region and transmissivity of the second light-transmitting region are different, transmissivity of the third light-transmitting region and transmissivity of the fourth light-transmitting region are different, a projection of the first light-transmitting region and a projection of the third light-transmitting region do not overlap in a direction perpendicular to the first optical layer, beams on different bands are formed after incident light passes through the splitter, and the beams on the different bands are respectively received by corresponding light-receiving regions; and
wherein a partial structure of the camera module is embedded in the housing.

16. The electronic device according to claim 15, wherein the first light-transmitting region comprises a plurality of first optical units, the second light-transmitting region comprises a plurality of second optical units, a shape of the first optical unit and a shape of the second optical unit are the same, a size of the first optical unit and a size of the second optical unit are equal, and transmissivity of the first optical unit and transmissivity of the second optical unit are different.

17. The electronic device according to claim 15, wherein both the first optical unit and the second optical unit are quadrangular prism structures.

18. The electronic device according to claim 15, wherein when the incident light is visible light, the beams on three different bands are formed after the incident light passes through the splitter; and
when the incident light comprises visible light and invisible light, the beams on four different bands are formed after the incident light passes through the splitter.

19. The electronic device according to claim 15, wherein a thickness range of the splitter is from 1 micron to 10 microns, and thickness of the splitter is a distance between a surface of the splitter facing away from the photodiode and a surface facing toward the photodiode.

20. The electronic device according to claim 16, wherein the first optical unit and the second optical unit are each made of one or more of silicon dioxide, silicon nitride, titanium dioxide, or gallium nitride.
